(19) United States
(12) Patent Application Publication
(10) Pub. No.: US 2009/0208881 A1
(43) Pub. Date: Aug. 20, 2009

(54) IMMERSION ULTRAVIOLET PHOTOLITHOGRAPHY PROCESS

(75) Inventor: Jean-Louis Imbert, Seyssinet (FR)

Correspondence Address: LOWE HAUPTMAN & BERNER, LLP, 1700 DIAGONAL ROAD, SUITE 300, ALEXANDRIA, VA, 22314, US

(73) Assignee: COMMISSARIAT A L'ENERGIE ATOMIQUE, Paris (FR)

(21) Appl. No.: 12/360,203

(22) Filed: Jan. 27, 2009

(30) Foreign Application Priority Data
Feb. 19, 2008 (FR) 0800884

(51) Int. Cl. G03F 7/00

(52) U.S. Cl. 430/323

(57) ABSTRACT

The invention relates to ultraviolet photolithography at 193 nanometres or 157 nanometres. To maximize resolution, optics having a very high numerical aperture are used, but without photoresists of sufficient index to best benefit from this high numerical aperture. It is proposed to use standard resists (PR) but with a thickness that is so small that they will be exposed locally by evanescent waves in the case of total internal reflection of the rays at very high angle of incidence, despite the presence of an immersion liquid (LQ) between the projection optics (OL) and the photoresist (PR).

### RELATED APPLICATIONS

The present application is based on, and claims priority from, French Application Number 0800884, filed Feb. 19, 2008, the disclosure of which is hereby incorporated by reference herein in its entirety.

### FIELD OF THE INVENTION

The invention relates to very-high-resolution photolithography.

### BACKGROUND OF THE INVENTION

At the present time, to obtain extremely narrow design features, notably for the production of electronic or optical circuits, photolithography machines are used that operate at ultraviolet wavelengths, conventionally 193 nanometres or even 157 nanometres.

Attempts have been made to use much shorter wavelengths, and therefore enable even smaller features to be produced: the envisaged wavelength is 13.6 nanometres (in the extreme ultraviolet), but the mask fabrication processes are much more complex.

The aim is therefore to seek to maximize resolution using conventional ultraviolet wavelengths, and notably a wavelength of 193 nanometres (obtained by an argon fluoride excimer laser).

The optical resolution limit is defined by a quantity d given by the formula d=λk/NA, where λ is the wavelength, NA is the numerical aperture and k is a corrective factor close to 1 if particular exposure process tricks are not taken into account and possibly down to 0.3 or even below this if such tricks are taken into account. The numerical aperture NA is equal to nsinθₘ, where n is the optical index of the last medium through which the UV passes and θₘ is the most extreme angle that the optical system can deliver.

One means of improving the resolution (i.e. reducing the quantity d) therefore consists in increasing the numerical aperture NA. However, increasing the numerical aperture poses a problem when the optics are placed in air, i.e. when an air layer is interposed between the optics and the photolithographic resist which it is sought to expose, in order to define a feature to be etched. This is because if the numerical aperture is greater than 1, the interface between the glass of the optics (or any other transparent material) and the air tends to prevent the high-incidence rays from the final lens of the optics from exiting towards the air and then towards the resist.

The exit lens of the optical system can therefore be placed in direct contact with a photolithographic resist of index greater than or equal to the numerical aperture of the optics. In this case, the high-incidence light rays continue to exit the optics and penetrate the resist. However, it should be understood that placing the optics in direct contact with the resist poses problems if an industrial photolithography is to be carried out: it is difficult to contact large areas and there is a risk of damaging either the resist layer or even the surface of the final lens of the optics.

This is why it has been conceived in the prior art to interpose a liquid, called an immersion liquid, between the lens and the photolithographic resist to be exposed. In order for the high-incidence light rays to be able to exit the optics and penetrate the resist, in order to expose it, it is necessary not only for this immersion liquid to be transparent at the wavelength used but also for it to have, at this wavelength, a refractive index greater than the value of the numerical aperture of the optics. If the refractive index of the immersion liquid were to be lower than the numerical aperture of the optics, the high-incidence rays would not exit the final lens. The index of the resist must also be greater than the numerical aperture.

Trials have therefore been conducted in the prior art, for a 193 nm or 157 nm wavelength, with optics having numerical apertures of about 1.3 using silica, an immersion fluid which initially was water but which it has been attempted to replace with liquids having indices ranging from about 1.54 to 1.60, and a photoresist having the highest possible index, possibly ranging from 1.6 to 1.75.

However, if it is desired to improve the resolution further, it is necessary to increase the numerical aperture of the optics, notably using lens materials of very high index (for example greater than 2, in order to obtain a numerical aperture greater than 1.7); a problem then arises because it is necessary to have an immersion liquid and a photoresist both having indices greater than 1.7.

### SUMMARY OF THE INVENTION

However, it is very difficult to find photoresists of such a high index.

It is for this reason that the invention proposes to use a photolithography process in which a high-index transparent immersion liquid is used, in order to avoid having the resist in direct contact with the optics and to avoid the optics being in air or in water (which has an insufficient index), but in which a photolithographic resist is provided that has an index lower than that of the immersion liquid and has a very small thickness, so that, for the high-incidence rays, the resist is exposed over its entire thickness not by the refracted rays in the resist but by the evanescent waves present at the interface, at the point where these high-incidence rays undergo total reflection because of their angle of incidence and because of the ratio of the liquid index to the resist index.

The term “photolithographic resist” is understood to mean the actual resist itself or the resist covered with a thin protective film, called a “top coat” when this thin film exists.

The resist thickness is then preferably between 0.1 and 0.5 times the exposure wavelength.

Thus, the invention provides a photolithography process for producing an etched feature in a layer deposited on a substrate, comprising the exposure of a photoresist having a refractive index equal to or less than 1.7 by an ultraviolet light beam through projection optics having a high numerical aperture (equal to or greater than 1.7), these optics including a solid projection lens having a high refractive index (preferably greater than 1.7), characterized in that a layer of immersion liquid, transparent at the wavelength used, is interposed between the lens and the photoresist, the refractive index of said liquid at this wavelength being equal to or greater than the numerical aperture of the optics, and in that the index of the immersion liquid is greater than that of the resist and the thickness of the resist is between about 0.1 and 0.5 times the wavelength of the exposure beam.

Over such a small thickness, the evanescent waves for the most extreme rays (taking into account the value of the numerical aperture of the optics) are present in the resist and expose it.

Thus, by dint of this process, it is unnecessary to develop resists of extremely high index, nor is it necessary for there to be direct contact between a lens and the resist, which would run the risk of degrading one or other of them.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 shows the general principle of the photolithography process according to the invention;

FIG. 2 shows the general action of a light ray on a photoresist when the angle of incidence of this ray is smaller than that for total internal reflection (FIG. 2a) and when the angle of incidence is greater than that for total internal reflection (FIG. 2b); and

FIG. 3 shows the action of a light ray on a photoresist having a very small thickness when the angle of incidence is smaller than that for total internal reflection (FIG. 3a) and when the angle of incidence is greater than that for total internal reflection (FIG. 3b).

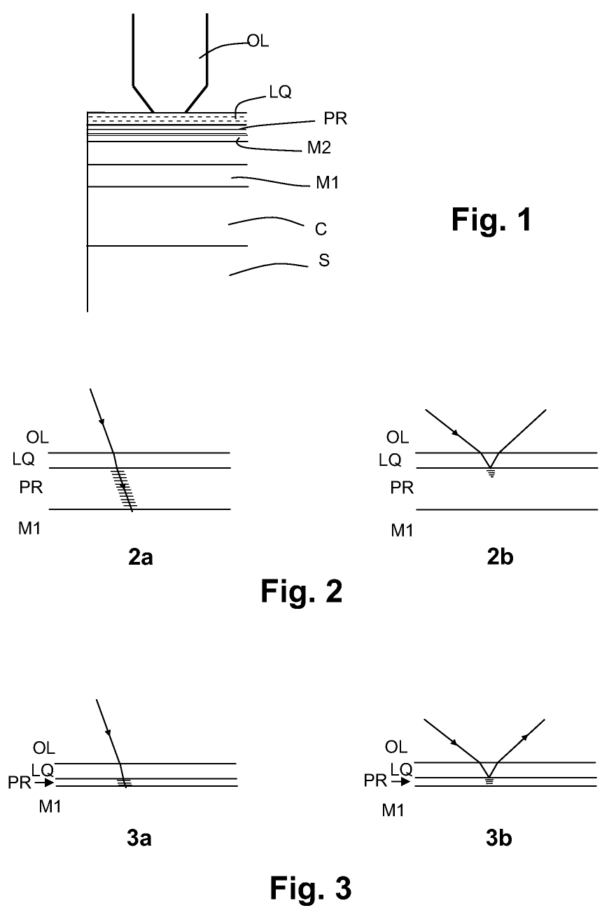

FIG. 1 shows schematically image projection optics OL operating in ultraviolet at a wavelength which is preferably 193 nm but which could also be 157 nm. The image is intended to expose a photoresist PR, which reacts at this wavelength. The resist is deposited on layers to be etched, which are themselves deposited on a planar substrate S.

### DETAILED DESCRIPTION OF THE INVENTION

For ease of examination, FIG. 1 has not been drawn to scale.

In the example shown, it is considered that the layers deposited on the substrate S comprise a superposition of a layer C to be etched, a first layer M1, which serves for the etching operations, and a second layer M2, which also serves for the etching operations. The reasons for this superposition will be explained later. The photoresist PR is deposited on the superposition, and therefore on the second layer M2.

The optics OL conventionally comprise a number of lenses (not shown) and have a numerical aperture as high as possible—in practice, it is hoped to obtain a numerical aperture equal to or greater than 1.7, using solid materials of sufficient index that are transparent at the wavelength used.

Typically, it is possible to use a transparent material of 2.15 index at the 193 nanometre wavelength, namely a lutetium aluminium garnet of cubic structure, in order therefore to obtain optics with a numerical aperture of between 1.7 and 1.8. The final lens of the optics OL is made from this material.

These optics are not in direct contact with the photoresist layer so as not to damage either the optics or the resist. Nor are the optics separated from this resist by an air layer, since air has much too low a refractive index (about 1), preventing the high-incidence rays from exiting the optics OL.

An immersion liquid LQ is therefore interposed between the glass of the final lens of the optics OL and the photoresist. This immersion liquid must be as transparent as possible, and consequently it is placed as a very thin film in the general case in which it is not sufficiently transparent. The order of magnitude of the envisaged liquid layer thickness is a few tens of microns, but this thickness may decrease to below 1 micron if the optical absorption coefficient of the liquid at the wavelength in question is too high. The liquid must have a refractive index equal to or greater than the numerical aperture of the optics OL, i.e., in the example given, greater than 1.7 or 1.8.

The following liquids may be used as immersion liquid:
an SnCl.2H₂O/glycerol mixture: 1.76 index in the visible, higher index (about 1.95) in 193 nm ultraviolet;
CH₂I₂: 1.738 index in the visible, higher index (about 1.93) in 193 nm ultraviolet;
sodium iodide or caesium iodide: 1.7 to 1.8 index in the visible, higher index (about 2) in 193 nm ultraviolet;
arsenic tribromide, or a mixture based on arsenic tribromide and arsenic disulphide in the presence of selenium compounds: 2.1 index in the visible, higher index (about 2.3) in 193 nm ultraviolet (for example, series H and EH from the US company Cargille).

A liquid thickness of at most 50 microns and preferably less than 100 nanometres will be used for these liquids, which have a not insignificant absorption and are therefore sufficiently transparent only at very small thickness.

The photoresist PR has a refractive index that has to be greater than the numerical aperture of the optics.

Unfortunately, an industrially usable photoresist that would have such a refractive index when the numerical aperture is very high has not been found.

FIG. 2 shows what happens when a light ray of moderate angle of incidence exits the optics and penetrates the immersion liquid (FIG. 2a) and when a very high-incidence ray exits the optics and penetrates the immersion liquid (FIG. 2b). In the first case (FIG. 2a), the light ray can penetrate the resist and expose it over its entire depth. In the second case (FIG. 2b), the light ray is totally reflected at the immersion liquid/resist interface and the resist is not exposed.

However, theory shows that in the second case the interaction between the electromagnetic light wave with the interface between two layers of different refractive index produces not only a totally reflected wave, which propagates on exiting the immersion liquid, but also a standing wave, which does not propagate and is localized in the immediate vicinity of the interface. This wave is called an evanescent wave, its particular characteristic being that it has an amplitude that very rapidly decreases with depth beneath the interface.

The invention proposes to give the photoresist a very small thickness enabling it to be exposed by the evanescent wave even for the incident rays that undergo total internal reflection at the interface between the immersion liquid and the resist. According to the invention, a resist thickness of between 0.1 times and 0.5 times the ultraviolet wavelength used is chosen. The full benefit of the resolution provided by using projection optics having a very high numerical aperture is therefore enjoyed, without the degradation due to total internal reflection of the very-high incidence rays.

Thus, it has been found that, using a standard photoresist having a refractive index smaller than the numerical aperture of the optics, but giving it a thickness of between 0.1 and 0.5 times the wavelength, even the rays of highest angle of incidence can be used to expose the resist over its entire depth.

FIG. 3, which is similar to FIG. 2, shows what happens in the case of rays of moderate angle of incidence (FIG. 3a) and in the case of rays having a very high angle of incidence (FIG. 3b). In the first case, the resist is exposed by the wave that propagates through the resist after refraction. In the second case, the resist is exposed by the evanescent wave, which possesses an eigenenergy.

The resist thus exposed to the ultraviolet is then developed, in order to remove the unexposed parts or the exposed parts depending on whether the resist is a positive or negative resist. The development leaves behind resist zones that define the etching features. These zones protect the subjacent layers. A selective etchant, which etches a subjacent layer more rapidly than the resist, is used to etch features beneath the resist.

However, it will be understood that the very small thickness of resist used (for example 20 to 100 nanometres) will have greater difficulty in resisting etchants than conventional thicknesses of hundreds of nanometres. This is why it is desirable to etch by successive transfer of features in several subjacent layers.

This is the reason why FIG. 1 shows a substrate S covered with superposed layers C, M1, M2, the layer C being the layer to be finally etched with the features defined by exposing the resist, and the layers M1 and M2 being intermediate masking layers used during the etching operation.

The thin layer M2 is firstly etched, then this layer is used as etching mask to etch the layer M1 and then the layer M1 (or the combination of M1 and M2) is used to etch a layer C located beneath the layer M1.

To give an example, the following masking layers may be used:
a silicon oxide layer M2 10 to 20 nanometres in thickness; and
an amorphous carbon layer M1, called “inert layer”, about 100 nanometres in thickness.

The etching selectivity between the resist layer and the layer M2 must be in a ratio of at least 3 to 5 (i.e. the ratio of the etching rate of the layer M2 to that of the resist). In the example given below (silicon oxide layer M2 10 to 20 nanometres in thickness), at most about 5 nanometres of resist will be consumed when etching the oxide.

If the etching selectivity of the oxide with respect to the layer M2 is less than 3, it may be pointed out that the etching can nevertheless proceed if a certain degradation of the etching profile is accepted. The image transferred into the layer M2 will then as it were be a more fuzzy image than the image of the resist features developed after exposure.

For etching the carbon layer M1 using the oxide layer M2 as masking layer, it is easy to find etchants having a high selectivity, i.e. with a carbon etching rate at least ten times greater than the oxide etching rate, and consequently the layer M1 may be much thicker than the layer M2. It is important to have a sufficiently thick layer M1 in order subsequently to etch the layer C.

Returning to exposure of the photoresist PR, and more particularly to the exposure caused by the rays having an angle of incidence higher than the limiting angle permitted by the difference in index between the immersion liquid, it may be demonstrated by theoretical calculation that the intensity of the evanescent waves may be expressed in the form:

I=e^{-z/P}

where z is the depth variable in the resist starting from the immersion liquid/resist interface and P is a quantity that can be likened to a depth and is equal to:

P=λ/[4π(nₑ² sin² θ−nᵣ²)^{1/2}]

where λ is the wavelength, nₑ is the index of the immersion liquid, nᵣ is the index of the resist and θ is the angle of incidence of a ray undergoing total internal reflection.

For example, if the index of the liquid is 2.1 and the index of the resist is 1.7 and if the wavelength is 193 nanometres and the angle of incidence is 60°, the intensity I is expressed as I=e^{-0.42z}, z being in nanometres, and the depth P down to which the energy of the evanescent waves can be used significantly (at the depth P, the energy is 2.7 times smaller than that present immediately beneath the interface) may be about 25 nanometres. This means that it is possible to use a resist layer having a thickness of about 25 nanometres if it can be successfully irradiated with an intensity 2.7 times lower than at the interface. If a liquid index closer to that of the resist is chosen, the quantity P may be significantly increased.

Preferably, the resist thickness is between 20 and 60 nanometres.

An example of a photolithography apparatus using an immersion liquid is given in the patent application published under the number US 2006/0072088. This can be used within the context of the present invention. In particular, it comprises a system for delivering this liquid, which injects a liquid between the external surface of the illumination optics and the surface of the wafer that has to undergo etching. The term “surface of the wafer” is understood here to mean the surface of the substrate S covered not only with the layer C to be etched and with the masking layers M1 and M2, but also with the resist PR. The distance between the external surface of the optics and the surface of the wafer is less than 50 microns, but may be much smaller (for example about 100 nanometres) if, for a 50 micron thickness, the immersion liquid is not sufficiently transparent. If possible, fluid is delivered all around the wafer so as to have a uniform distribution.

The wafer is placed on a positioning table that enables the wafer to be shifted stepwise when the exposure takes place stepwise.

One possible protocol for using the process according to the invention may consist in moving the wafer through a step corresponding to the spacing between two adjacent chips on the wafer, while maintaining an immersion liquid film with a thickness of the order of 1 millimetre between the projection optics and the wafer, with or without replenishment of the fluid. When the next chip arrives in the exposure position, the positioning table adjusts the plane of the wafer surface with the image plane formed by the projection optics. The wafer is then moved closer so as to be at the intended distance, equal to or less than 50 microns, and the image is exposed to the ultraviolet rays by the projection optics. The flow of immersion liquid may be interrupted during the step of moving the wafer close to the optics.

The table is then again lowered down to a distance of the order of 1 millimetre and the operation is repeated for a new chip exposure.

Another possible protocol consists in positioning the height of the wafer right from the first exposure and then in displacing the wafer stepwise from chip to chip without changing this height, during which the immersion liquid may or may not be replenished. This obviously assumes that the chosen working distance, between the wafer and the optics, is sufficient not to risk a roughness peak on the wafer scraping the optics during the displacement. It is therefore preferable to measure the roughness of the wafer beforehand, by means of a roughness meter, and if possible to use wafers of higher planarity than that of wafers treated using standard processes.

To be able to use the invention, it is necessary for the image provided by the projection optics OL to form at the point where the photoresist is located and it is therefore necessary to design the optics according to the height of the space filled with immersion liquid between the wafer and the optics. A parallel-sided plate may be added beneath the final lens of the projection optics, the thickness of said plate being chosen so as to adjust the position of the image formed for given projection optics, since the image displacement is proportional to the thickness of the parallel-sided plate.

If the thickness of immersion liquid has to vary, means should preferably be provided for modifying the position of the image plane in correspondence with the desired variation. These means may be mechanical or pneumatic or electrical.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. Photolithography process for producing etched features in a layer deposited on a substrate, comprising:
exposing a photoresist having a refractive index equal to or less than 1.7 by an ultraviolet light beam through projection optics having a high numerical aperture (equal to or greater than 1.7), these optics including a solid projection lens having a high refractive index (preferably greater than 1.7), wherein a layer of immersion liquid, transparent at the wavelength used, is interposed between the lens and the photoresist, the refractive index of said liquid at this wavelength being equal to or greater than the numerical aperture of the optics, and in that the index of the immersion liquid is greater than that of the resist and the thickness of the resist is between about 0.1 and 0.5 times the wavelength of the exposure beam.

2. The process according to claim 1, wherein the light beam is an ultraviolet beam at a wavelength of 193 nanometres or 157 nanometres.

3. The process according to claim 1, wherein the surface of the resist is placed, during exposure, at a distance of 100 nanometres to 50 microns from the projection optics.

4. Photolithography process according to claim 1, wherein the photoresist is deposited on intermediate masking layers (M1 and M2) which are themselves deposited on a layer (C) to be etched according to the pattern of exposure of the resist.

5. The photolithography process according to claim 4, wherein the first masking layer (M1) deposited on the layer (C) to be etched is an amorphous carbon layer.

6. The photolithography process according to claim 4, wherein the second masking layer (M2) is a thin silicon oxide layer from 10 to 20 nanometres in thickness.

7. The process according to claim 2, wherein the surface of the resist is placed, during exposure, at a distance of 100 nanometres to 50 microns from the projection optics.

8. The photolithography process according to claim 5, wherein the second masking layer (M2) is a thin silicon oxide layer from 10 to 20 nanometres in thickness.
